(19) United States
(12) Patent Application Publication
(10) Pub. No.: US 2017/0205909 A1
(43) Pub. Date: Jul. 20, 2017

(54) Touch Panel and Method of Fabricating the Same

(71) Applicant: SHENZHEN CHINA STAR OPTOELECTRONICS TECHNOLOGY CO., LTD., GUANGDONG (CN)

(72) Inventor: Sikun HAO, GUANGDONG (CN)

(21) Appl. No.: 15/030,606

(22) PCT Filed: Feb. 25, 2016
(86) PCT No.: PCT/CN2016/074511

§ 371 Date: Apr. 20, 2016

(30) Foreign Application Priority Data
Jan. 19, 2016 (CN) 201610034176.8

(51) Int. Cl. G06F 3/044; H01L 27/12; G06F 3/041

(52) U.S. Cl. CPC G06F 3/044; G06F 3/0416; G06F 3/0412; H01L 27/1262; G06F 2203/04103

(57) ABSTRACT

A touch panel includes: a substrate; a first metallic layer for forming a gate of a thin-film transistor (TFT); a gate insulating layer; a second metallic layer for forming a data line, a source and a drain of the TFT; an isolation layer penetrated by a first hole; a third metallic layer for forming a driving line for transmitting a driving signal and a common voltage; a passivation layer, layered with and deposited on the isolation layer, penetrated by the first hole and a second hole, and the second hole aiming at the data line; a pixel electrode, connected to the source or the drain through the first hole; a driving electrode, connected to the driving line through the second hole; and a sensing electrode, for transmitting a sensing signal and the common voltage. The driving electrode and the sensing electrode are used as common electrode layers.

### BACKGROUND OF THE INVENTION

1. Field of the Invention

The present invention relates to the field of capacitive sensing techniques, and more particularly, to a touch panel using capacitive sensing components and a method of fabricating the touch panel.

2. Description of the Prior Art

Liquid crystal displays show vivid colors while keeping a low power consumption and flicker rate, and thus have become mainstream in displays, being widely applied in electronic devices such as mobile phones, cameras, computer screens, and televisions.

Touch panels are sturdy, durable, and space saving. They react fast and are easy to interact with. Via touch panel technology, users may operate electronic devices by simply touching an icon or a text on a touch screen. This direct way of human-machine interaction has brought revolutionized convenience to users who are not so good at conventional computer operation.

Nowadays many electronic devices have screens manufactured via both liquid crystal display technology and touch panel technology. These liquid crystal touch panels, born with advantages from both technologies, are a great market success. However, due to structural facts of conventional liquid crystal displays, conventional liquid crystal touch panels have their sensing electrodes, which realize the touch function, set under pixel electrodes of liquid crystal displays. This lays difficulty for sensing electrodes to sense user touch, and thus decreases sensitivity of touch panels.

A conventional capacitive sensing component where a first transparent conductive line and a second transparent conductive line are mutally overlapped . The first conductive line and the second conductive line are connected to a driving line arranged horizntally and a sensing line arranged vertically, respectively. But parasitic capacitance often occurs at the crossing of the driving line and the sensing line. The parasitic capacitance has an influence on the aperture ratio of the pixel. Also, the bezel of the display near the active area has to be widened since a lot of driving lines are arranged, which contradicts modern displays with narrow bezels.

### SUMMARY OF THE INVENTION

Therefore, an object of the present invention is to propose an in-cell touch panel for resolving the aforementioned technical problem. The in-cell touch panel is an integration of a capacitive touch panel and an in plane switching (IPS) panel.

According to the present invention, a touch panel comprises: a substrate; a first metallic layer, arranged on the substrate, for forming a gate of a thin-film transistor (TFT); a gate insulating layer, arranged on the first metallic layer; a second metallic layer, arranged on the gate insulating layer, for forming a data line, a source of the TFT, and a drain of the TFT; an isolation layer, arranged on the second metallic layer, penetrated by a first hole, and the first hole aiming at the source or the drain; a third metallic layer, arranged on the isolation layer, for forming a driving line, and the driving line used for transmitting a driving signal and a common voltage; a passivation layer, layered with and deposited on the isolation layer, penetrated by the first hole and a second hole, and the second hole aiming at the data line; a pixel electrode, connected to the source or the drain through the first hole; a driving electrode, connected to the driving line through the second hole; and a sensing electrode, for transmitting a sensing signal and the common voltage. The driving electrode and the sensing electrode are used as common electrode layers.

In one aspect of the present invention, the pixel electrode, the sensing electrode, and the driving electrode are formed by an identical conductive layer.

In another aspect of the present invention, the conductive layer is made of indium tin oxide (ITO) or metal.

In another aspect of the present invention, the data line is used for transmitting a data voltage to the pixel electrode layer through the TFT.

In still another aspect of the present invention, the data line is used for transmitting the data voltage to the pixel electrode layer through the TFT when the driving line transmits the common voltage to the driving electrode.

In yet another aspect of the present invention, the data line stops transmitting the data voltage to the pixel electrode layer when the driving line transmits the driving signal to the driving electrode.

According to the present invention, a method of fabricating a touch panel, comprises: forming a first metallic layer on a substrate; etching the first metallic layer, for forming a gate of a thin-film transistor (TFT); forming a gate insulating layer on the gate of the TFT; forming a second metallic layer on the gate insulating layer; etching the second metallic layer, for forming a data line, a source of the TFT, and a drain of the TFT; forming an isolation layer on the data line, the source of the TFT, and the drain of the TFT; etching the isolation layer, for forming a first hole penetrating the isolation layer, and aiming the first hole at the source or the drain; depositing the a third metallic layer on the isolation layer; etching the third metallic layer, for forming a driving line and a sensing line over the data line, the driving line used for transmitting a driving signal and a common voltage, and the sensing line used for transmitting a sensing signal and the common voltage; depositing a passivation layer on the isolation layer and the driving layer; etching the passivation layer, for forming the first hole and the second hole penetrating the passivation layer, and arranging the second hole over the driving line; depositing a conductive layer on the passivation layer, the driving line, the source, or the drain; etching the conductive layer for forming a pixel electrode, a driving electrode, and a sensing electrode, the pixel electrode connected to the source or the drain through the first hole, the driving electrode connected to the driving line through the second hole, the sensing electrode used for transmitting a sensing signal and the common voltage, and the driving electrode and the sensing electrode used as common electrode layers. The driving electrode and the sensing electrode are used as common electrode layers.

In one aspect of the present invention, the conductive layer is made of indium tin oxide (ITO) or metal.

In another aspect of the present invention, before the step of forming the second metallic layer on the gate insulating layer, the method further comprises: forming an amorphous (a-Si) layer on the gate insulating layer; and etching the a-Si layer for forming a semiconductor layer of the TFT.

Compared with the conventional technology, the driving line arranged in the array substrate of the touch panel in the present invention can transmit common voltage and driving signals without adding extra driving signal lines for transmitting driving signals. According to the present invention, the bezel of the touch panel is not widened even though driving signal lines are arranged in the touch panel. Because the driving electrode, the sensing electrode, and the pixel electrode are formed on the same conductive layer, the processes of fabrication are simplified, and the costs are reduced. Also, parasitic capacitance does not easily occur even if extra driving signal lines are arranged in the touch panel. Touch sensitivity improves as well because the driving electrode, the sensing electrode, and the pixel electrode are fabricated from indium tin oxide (ITO) or metal.

These and other features, aspects and advantages of the present disclosure will become understood with reference to the following description, appended claims and accompanying figures.

### BRIEF DESCRIPTION OF THE DRAWINGS

FIG. 1 is a schematic diagram of a display device according to one preferred embodiment of the present invention.

FIG. 2 is a schematic diagram of distribution of a touch capacitor in a touch area in a display device according to the embodiment of the present invention.

FIGS. 3A and 3B are cross-sectional views of a touch panel 100 according to a preferred embodiment of the present invention.

FIG. 4 through FIG. 11 are schematic diagrams of the array substrate in the touch panel as shown in the working drawing FIG. 3.

### DETAILED DESCRIPTION OF THE PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

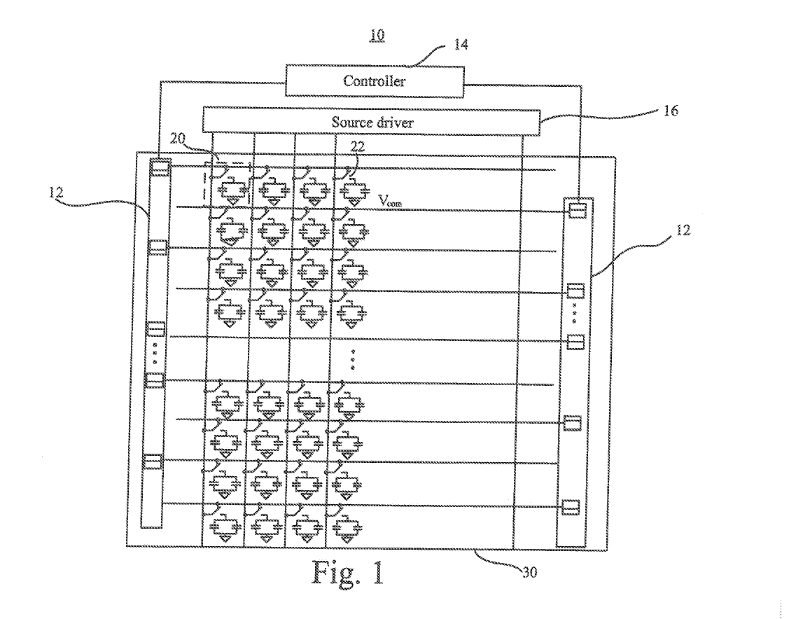

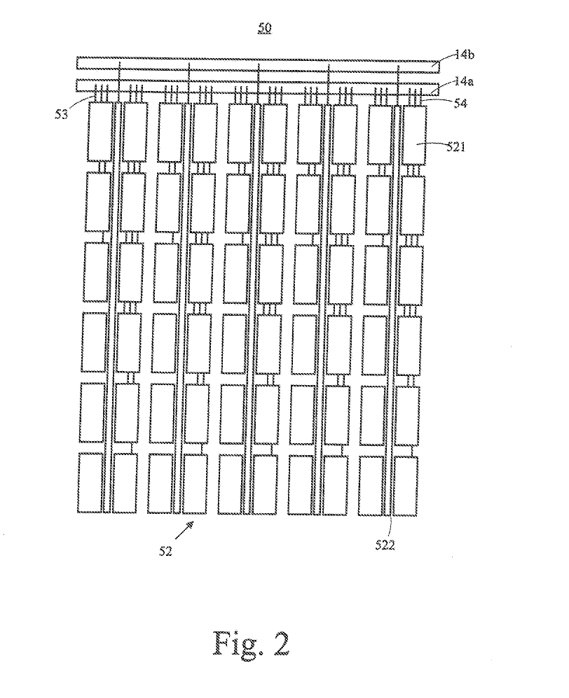

Please to refer to FIG. 1 and FIG. 2. FIG. 1 is a schematic diagram of a display device 10 according to one preferred embodiment of the present invention. FIG. 2 is a schematic diagram of distribution of a touch capacitor in a touch area 50 in a display device 10 according to the embodiment of the present invention. The display device 10 comprises a touch panel 100. The touch panel 100 is a liquid crystal panel with a touch function. The touch panel 100 comprises a display area 30 and a touch area 50. The display area 30 is used for showing images. The touch area 50 is used for sensing where a human's finger touches. The display device 10 comprises a gate driver 12, a controller 14, and a source driver 16. A plurality of pixels arranged in a matrix are disposed in the display area 30. Each of the plurality of pixels comprises three pixel units 20. Theses three pixel units 20 are the primary colors—red (R), green (G), and blue (B). The gate driver 12 outputs a scanning signal at regular intervals for turning on transistors 22 on each row successively. Meanwhile, the source driver 16 outputs a corresponding data signal to all of the pixel units 20 on one column so that all of the pixel units 20 on the column can be fully charged for showing diverse grayscales based on the difference of voltage between the data signal and the common voltage Vcom. When all of the pixel units 20 on the same row are fully charged, the scanning signal for the row is turned off by the gate driver 12. Then, the gate driver 12 outputs a scanning signal again to turn on the transistors 22 on the next row. The source driver 16 charges and discharges the pixel units 20 on the next row. According to the step, all of the pixel units 20 are fully charged in the end. Subsequently, the pixel units 20 on the first row are charged again.

Please refer to FIG. 2. The touch area 50 comprises a plurality of capacitive driving electrodes 521, a plurality of sensing electrodes 522 (touch electrode layers 52), a driving lines 53, and a sensing line 54. The plurality of capacitive driving electrodes 521 and the plurality of sensing electrodes 522 are mutually insulated. The plurality of capacitive driving electrodes 521 and sensing electrodes 522 are distributed in arrays. Each of the plurality of capacitive driving electrodes 521 can be shaped as round, triangle, or any other kind of shape. Each of the plurality of sensing electrodes 522 can be shaped as round, triangle, or any other kind of shape as well.

Each of the plurality of driving electrodes 521 is connected to a corresponding driving line 53. The controller 14 comprises a driving signal unit 14a. The driving signal unit 14a outputs a driving signal to the driving electrode 521 through the driving line 53. Each of the plurality of sensing electrodes 522 is connected to a corresponding sensing line 54. The sensed sensing signal is transmitted to a driving signal unit 14b of the controller 14. The driving signal unit 14a outputs the driving signal to each of the plurality of driving electrodes 521 periodically. The capacitor between the driving electrode 521 and the sensing electrode 522 is a fixed value before a human's finger touches the monitor. When the human's finger touches the monitor, for example, operating functions on the monitor, the capacitance between the driving electrode 521 and the sensing electrode 522 which the touched position on the monitor corresponds to is subject to the human body and varies accordingly. So a sensing signal sent back by the sensing electrode 522 near the touched position is different from a sensing signal sent back by the sensing electrode 522 far away from the touched position. It implies that variations of capacitive values tell where a human's finger touches after the controller 14 senses, which implements the touch function.

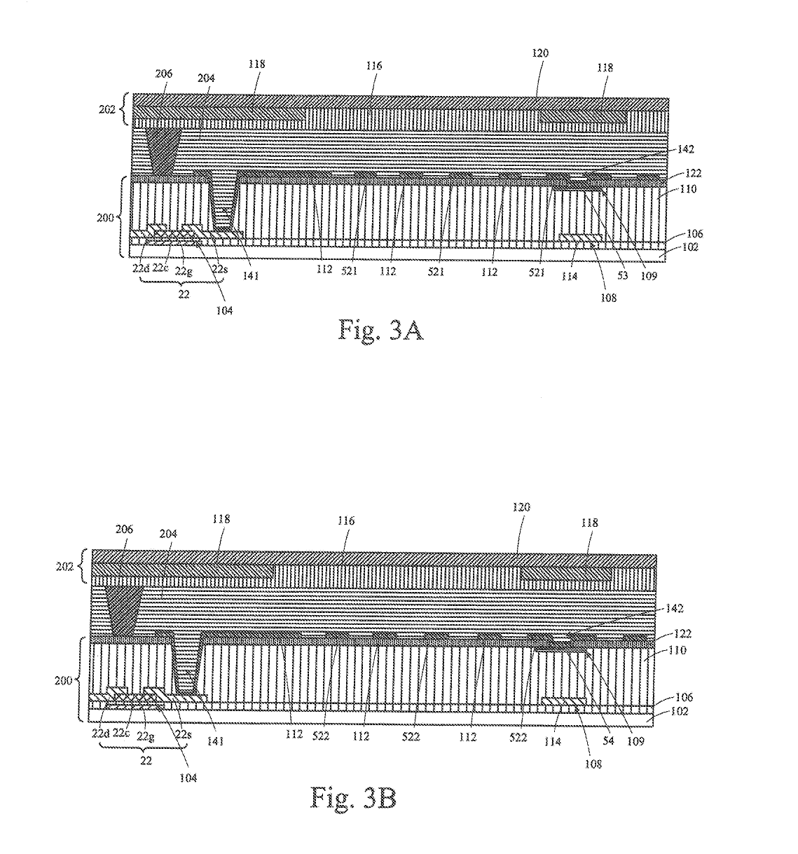

Please refer to FIGS. 3A and 3B. FIGS. 3A and 3B are cross-sectional views of a touch panel 100 according to a preferred embodiment of the present invention. The touch panel 100 shown in FIG. 3A is the same as that shown in FIG. 3B though the touch panel 100 is shown in different views. The touch panel 100 comprises an array substrate 200, a color film substrate 202, and a liquid crystal layer 204. A plurality of pixel electrode layers 112, a TFT 22, and a touch electrode 52 are arranged on the array substrate 200. The array substrate 200 comprises a glass substrate 102, a first metallic layer 104, a gate insulating layer 106, a second metallic layer 108, an isolation layer 110, a passivation layer 122, a third metallic layer 109, a pixel electrode layer 112, a driving electrode 521, and a sensing electrode 522. The first metallic layer 104 is arranged on the glass substrate 102 for forming a gate 22g of the TFT 22. The gate insulating layer 106 is arranged on the first metallic layer 104. A semiconductor layer formed by an a-Si layer is arranged on the gate insulating layer 106. The semiconductor layer is used as a semiconductor layer 22c of the TFT 22. The second metallic layer 108 is arranged on the gate insulating layer 106 for forming a source 22s of the TFT 22, a drain 22d of the TFT 22, and a data line 114. The data line 114 is used for transmitting a data signal transmitted from a source driver 16 to the TFT 22. The isolation layer 110 is arranged on the second metallic layer 108. A first hole 141 penetrates the isolation layer 110. The first hole 141 aims at the source 22s or the drain 22d. The third metallic layer 109 forms a driving line 53 and a sensing line 54. The driving line 53 and the sensing line 54 are arranged on the data line 114. The driving line 53 is used for transmitting a driving signal generate by the controller 14 and a common voltage Vcom. The sensing line 54 is used for transmitting a sensing signal back to the controller 14. The sensing line 54 can be used for receiving the common voltage Vcom as well. The passivation layer 122 covers an insulating layer 100. The first hole 141 penetrates the passivation layer 122. The second hole 142 penetrates the passivation layer 122, and the surface of the driving line 53 is shown. The driving electrode 521, the sensing electrode 522, and the pixel electrode layer 112 are all arranged on the passivation layer 122. The pixel electrode layer 112 is connected to the source 22s or the drain 22d through the first hole 141. The driving electrode 521 and the sensing electrode 522 are connected to the driving line 53 and the sensing line 54 through the formed second hole 142, respectively. The driving electrode 521, the sensing electrode 522, and the pixel electrode layer 112 are all formed by an identical conductive layer.

The driving electrode 521 and the sensing electrode 522 are used as the common electrodes layer in this embodiment. On one hand, the source driver 16 transmits data voltage to the pixel electrode 112 through the TFT 22 when the controller 14 transmits the common voltage to the driving electrode 521 through the driving line 53. The difference between the data voltage imposed on the pixel electrode 112 and the common voltage imposed on the driving electrode 521 (or the sensing electrode 522) pushes the liquid crystal molecules in the liquid crystal layer 204 between the pixel electrode 112 and the driving electrode 52 to rotate for showing diverse grayscales. On the other hand, the data line 114 stops transmitting the data voltage to the pixel electrode 112 when the controller 14 transmits the driving signal to the driving electrode 521 through the data line 53. At this time, the sensing electrode 522 transmits the sensed sensing signal to the controller 54. The liquid crystal molecules between the pixel electrode 112 and the driving electrode 521 (or the sensing electrode 522) keep the same rotating state. In other words, the driving electrode 521 and the sensing electrode 522 are used as the common electrodes for receiving the common voltage at the stage of image display and are used for sensing a touched and pressed position at the stage of touch and sense.

The color film substrate 202 comprises a color filter layer 116, a black matrix layer 118, and a glass substrate 120. The color filter layer 116 is used for filtering out light with different colors. The black matrix layer 118 is used for blocking light leakage. A spacer 116 is used for making room between the array substrate 200 and the color film substrate 202 for accommodating the liquid crystal layer 204. The driving line 53 is arranged in the vertical projecting area on the array substrate 200 on the black matrix layer 118 on the color film substrate 202 so as to reduce the influence of the driving line 53 on the aperture ratio.

Please refer to FIG. 4 to FIG. 11. FIG. 4 to FIG. 11 are schematic diagrams of the array substrate 200 in the touch panel 100 as shown in the working drawing FIG. 3A. As shown in FIG. 4, a glass substrate 102 is used. A deposition process for a metallic thin film is conducted. A first metallic layer (not shown) is formed on the surface of the glass substrate 102. Also, a first lithography etching is conducted using a first mask. The gate 22g of the TFT 22 and a scanning line (not shown) are formed after the first lithography etching. Although no scanning lines are shown in FIG. 4, the people skilled in this field are supposed to realize that the gate 22g is part of the scanning line.

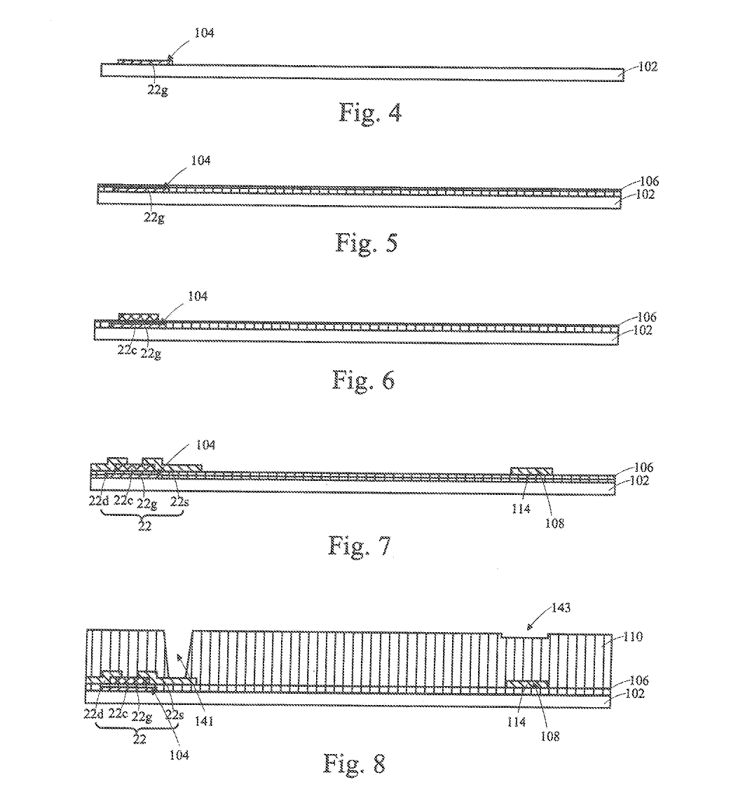

Please refer to FIG. 5. The gate insulating layer 106 made of SiNₓ is deposited. The gate insulating layer 106 covers the gate 22g.

Please refer to FIG. 6. An a-Si layer is deposited on the gate insulating layer 106 over the gate 22g. Subsequently, the a-Si layer is etched using a second mask for forming a semiconductor layer 22c. The semiconductor layer 22c is used as a semiconductor layer of the TFT 22.

Please refer to FIG. 7. The second metallic layer (not shown) is formed on the surface of the gate insulating layer 106. Also, the lithography etching is conducted using a third mask. The source 22s of the TFT 22, the drain 22d of the TFT 22, and the data line 114 are formed after the second lithography etching. The data line 114 is directly to the source 22s. The people skilled in this field are supposed to realize that the source 22s is part of the data line 114. In addition, the source 22s and the drain 22d can be switched.

Please refer to FIG. 8. The isolation layer 110 made of soluble polyfluoroalkoxy (PFA) is deposited. The isolation layer 110 covers the source 22s, the drain 22d, and the data line 114. The isolation layer 110 is etched using a fourth mask. Part of the isolation layer 110 on the drain 22d is removed for showing the surface of the drain 22d. The first hole 141 is formed on the drain 22d. A groove 143 is formed on the data line 114. In other words, the first hole 141 aims at the drain 22d.

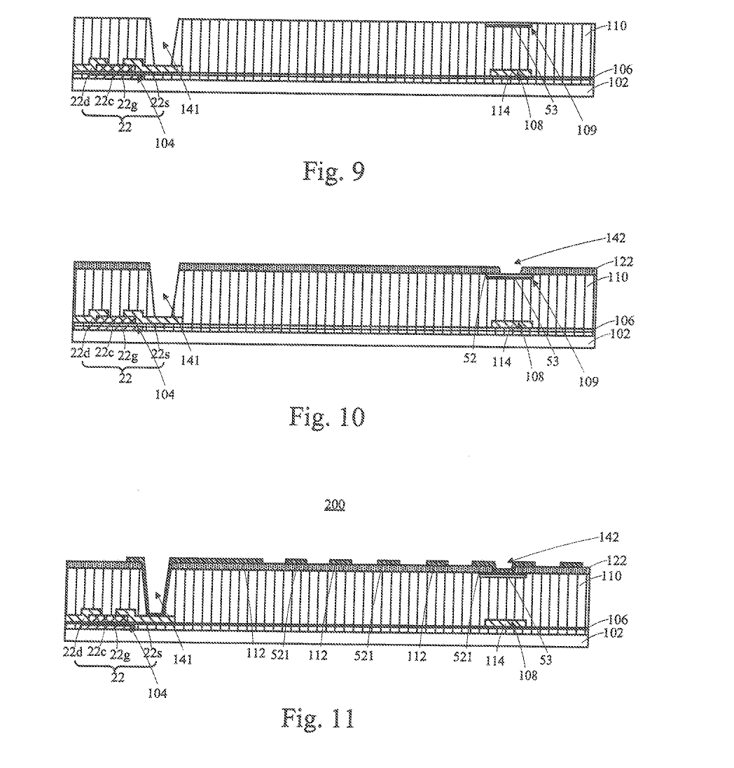

Please refer to FIG. 9. A third metallic layer (not shown) is formed on the isolation layer 110. Also, the third metallic layer is etched using a fifth mask for forming the driving line 53 at the groove 143. The driving line 53 is used for transmitting the driving signal and the common electrode.

Please refer to FIG. 10. A passivation layer 122 is deposited on the isolation layer 110 and the driving line 53. Subsequently, the passivation layer 122 is etched using a sixth mask for forming a first hole 141 penetrating the passivation layer 122 and a second hole 142 penetrating the passivation layer 122. The second hole 142 is arranged on the driving line 53.

Please refer to FIG. 11. A conductive layer (not shown) made of indium tin oxide (ITO), graphene, or metal is deposited. Subsequently, the insulating layer is etched using a seventh mask for forming the pixel electrode layer 112 and the driving electrode 521 simultaneously. The pixel electrode layer 112 is electrically connected to the drain 22d of the TFT 22 through the formed first hole 141. The driving electrode 521 is connected to the driving line 53 through the formed second hole 142. The pixel electrode layer 112 forms a plurality of pixel electrodes. The driving electrode 521 form a plurality of touch electrodes. The plurality of pixel electrodes and the plurality of touch electrodes are alternatively formed on the passivation layer 122.

The touch panel shown in FIG. 3A is the same as that shown in FIG. 313 so the touch panel shown in FIG. 3B can be fabricated according to the steps shown in FIG. 11 to FIG. 11. In other words, the step of forming the driving line 53 as shown in FIG. 9 can be adopted to form the sensing line 54 as shown in FIG. 3B. The step of forming the driving electrode 521 as shown in FIG. 11 can be adopted to form the sensing electrode 522 as shown in FIG. 3B.

At this time, the array substrate 200 is finished completely. The combination of the color film substrate 202 and the liquid crystal layer 204 forms the touch panel 100 proposed by this embodiment.

Further, the touch panel 100 can be an organic light-emitting diode (OLED) display panel with a touch function or other kinds of display panels in other embodiments.

Compared with the conventional technology, the driving line arranged in the array substrate of the touch panel in the present invention can transmit common voltage and driving signals without adding extra driving signal lines for transmitting driving signals. According to the present invention, the bezel of the touch panel is not widened even though driving signal lines are arranged in the touch panel. Because the driving electrode, the sensing electrode, and the pixel electrode are formed on the same conductive layer, the processes of fabrication are simplified, and the costs are reduced. Also, parasitic capacitance does not easily occur even if extra driving signal lines are arranged in the touch panel. Touch sensitivity improves as well because the driving electrode, the sensing electrode, and the pixel electrode are fabricated from indium tin oxide (ITO) or metal.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A touch panel, comprising:
a substrate;
a first metallic layer, arranged on the substrate, for forming a gate of a thin-film transistor (TFT);
a gate insulating layer, arranged on the first metallic layer;
a second metallic layer, arranged on the gate insulating layer, for forming a data line, a source of the TFT, and a drain of the TFT;
an isolation layer, arranged on the second metallic layer, penetrated by a first hole, and the first hole aiming at the source or the drain;
a third metallic layer, arranged on the isolation layer, for forming a driving line, and the driving line used for transmitting a driving signal and a common voltage;
a passivation layer, layered with and deposited on the isolation layer, penetrated by the first hole and a second hole, and the second hole aiming at the data line;
a pixel electrode, connected to the source or the drain through the first hole;
a driving electrode, connected to the driving line through the second hole; and
a sensing electrode, for transmitting a sensing signal and the common voltage;
wherein the driving electrode and the sensing electrode are used as common electrode layers, the data line is used for transmitting a data voltage to the pixel electrode layer through the TFT,
wherein the data line is used for transmitting the data voltage to the pixel electrode layer through the TFT when the driving line transmits the common voltage to the driving electrode, and the data line stops transmitting the data voltage to the pixel electrode layer when the driving line transmits the driving signal to the driving electrode.

2. The touch panel of claim 1, wherein the pixel electrode, the sensing electrode, and the driving electrode are formed by an identical conductive layer.

3. The touch panel of claim 2, wherein the conductive layer is made of indium tin oxide (ITO) or metal.

4. A touch panel, comprising:
a substrate;
a first metallic layer, arranged on the substrate, for forming a gate of a thin-film transistor (TFT);
a gate insulating layer, arranged on the first metallic layer;
a second metallic layer, arranged on the gate insulating layer, for forming a data line, a source of the TFT, and a drain of the TFT;
an isolation layer, arranged on the second metallic layer, penetrated by a first hole, and the first hole aiming at the source or the drain;
a third metallic layer, arranged on the isolation layer, for forming a driving line, and the driving line used for transmitting a driving signal and a common voltage;
a passivation layer, layered with and deposited on the isolation layer, penetrated by the first hole and a second hole, and the second hole aiming at the data line;
a pixel electrode, connected to the source or the drain through the first hole;
a driving electrode, connected to the driving line through the second hole; and
a sensing electrode, for transmitting a sensing signal and the common voltage;
wherein the driving electrode and the sensing electrode are used as common electrode layers.

5. The touch panel of claim 4, wherein the pixel electrode, the sensing electrode, and the driving electrode are formed by an identical conductive layer.

6. The touch panel of claim 5, wherein the conductive layer is made of indium tin oxide (ITO) or metal.

7. The touch panel of claim 4, wherein the data line is used for transmitting a data voltage to the pixel electrode layer through the TFT.

8. The touch panel of claim 7, wherein the data line is used for transmitting the data voltage to the pixel electrode layer through the TFT when the driving line transmits the common voltage to the driving electrode.

9. The touch panel of claim 7, wherein the data line stops transmitting the data voltage to the pixel electrode layer when the driving line transmits the driving signal to the driving electrode.

10. A method of fabricating a touch panel, comprising:
forming a first metallic layer on a substrate;
etching the first metallic layer, for forming a gate of a thin-film transistor (TFT);
forming a gate insulating layer on the gate of the TFT;
forming a second metallic layer on the gate insulating layer;
etching the second metallic layer, for forming a data line, a source of the TFT, and a drain of the TFT;
forming an isolation layer on the data line, the source of the TFT, and the drain of the TFT;
etching the isolation layer, for forming a first hole penetrating the isolation layer, and aiming the first hole at the source or the drain;
depositing the a third metallic layer on the isolation layer;
etching the third metallic layer, for forming a driving line and a sensing line over the data line, the driving line used for transmitting a driving signal and a common voltage, and the sensing line used for transmitting a sensing signal and the common voltage;
depositing a passivation layer on the isolation layer and the driving layer;
etching the passivation layer, for forming the first hole and the second hole penetrating the passivation layer, and arranging the second hole over the driving line;
depositing a conductive layer on the passivation layer, the driving line, the source, or the drain;
etching the conductive layer for forming a pixel electrode, a driving electrode, and a sensing electrode, the pixel electrode connected to the source or the drain through the first hole, the driving electrode connected to the driving line through the second hole, the sensing electrode used for transmitting a sensing signal and the common voltage, and the driving electrode and the sensing electrode used as common electrode layers;
wherein the driving electrode and the sensing electrode are used as common electrode layers.

11. The method of claim 10, wherein the conductive layer is made of indium tin oxide (ITO) or metal.

12. The method of claim 10, wherein before the step of forming the second metallic layer on the gate insulating layer, the method further comprises:
forming an amorphous (a-Si) layer on the gate insulating layer; and
etching the a-Si layer for forming a semiconductor layer of the TFT.
